(19) United States
(12) Patent Application Publication
(10) Pub. No.: US 2011/0260054 A1
(43) Pub. Date: Oct. 27, 2011

(54) ATOM PROBE PULSE ENERGY

(75) Inventor: Joseph H. Bunton, Madison, WI (US)

(73) Assignee: Imago Scientific Instruments Corporation, Madison, WI (US)

(21) Appl. No.: 12/092,066

(22) PCT Filed: Oct. 31, 2006
(86) PCT No.: PCT/US2006/042742

§ 371 Date: Oct. 6, 2008

Related U.S. Application Data
(60) Provisional application No. 60/731,727, filed on Oct. 31, 2005.

(51) Int. Cl. H01J 37/26

(52) U.S. Cl. 250/307

(57) ABSTRACT

The present invention relates to atom probe pulse energy. One aspect of the invention is directed toward a method that includes establishing a data relationship between pulse energy and bias energy for a target evaporation rate. In selected embodiments, establishing a data relationship can include determining an equivalent pulse fraction for a selected pulse energy and bias energy combination based on a local change in bias energy compared to a local change in pulse energy associated with the selected pulse energy and bias energy combination. Another aspect of the invention is directed toward a method that includes determining an equivalent pulse fraction for a first bias energy and pulse energy combination and/or a second bias energy and pulse energy combination based on the difference between the first bias energy and the second bias energy compared to the difference between the first pulse energy and the second pulse energy.

### CROSS-REFERENCE TO RELATED APPLICATION(S)

This application claims the benefit of U.S. Provisional Patent Application No. 60/731,727, filed Oct. 31, 2005, entitled ATOM PROBE PULSE ENERGY, which is fully incorporated herein by reference.

### TECHNICAL FIELD

Embodiments of the present invention relate to atom probe pulse energy, including methods for establishing atom probe data relationships between bias energies and pulse energies used in an atom probe.

### BACKGROUND

An atom probe (e.g., atom probe microscope) is a device which allows specimens to be analyzed on an atomic level. For example, a typical atom probe includes a specimen mount, an electrode, and a detector. During analysis, a specimen is carried by the specimen mount and a positive electrical charge (e.g., a baseline voltage) is applied to the specimen. The detector is spaced apart from the specimen and is negatively charged. The electrode is located between the specimen and the detector, and is either grounded or negatively charged. A positive electrical pulse (above the baseline voltage) and/or a laser pulse (e.g., photonic energy) are intermittently applied to the specimen. Alternately, a negative pulse can be applied to the electrode. Occasionally (e.g., one time in 100 pulses) a single atom is ionized near the tip of the specimen. The ionized atom(s) separate or “evaporate” from the surface, pass though an aperture in the electrode, and impact the surface of the detector. The elemental identity of an ionized atom can be determined by measuring its time of flight between the surface of the specimen and the detector, which varies based on the mass/charge ratio of the ionized atom. The location of the ionized atom on the surface of the specimen can be determined by measuring the location of the atom's impact on the detector. Accordingly, as the specimen is evaporated, a three-dimensional map of the specimen's constituents can be constructed.

Evaporation rate (Er), the number of ions detected per unit pulse, is a primary metric used to control/monitor the atom probe data collection process. Failure to accurately monitor or control Er can result in either little or no data being collected (Er˜0) or too many ionization events detected. Additionally, if the induced field is too great, the specimen can fracture, damaging the specimen and possibly other atom probe components. Furthermore, if the Er is too high where multiple ions are liberated or evaporated on the same pulse, data “noise” can result because the detected ions cannot be properly correlated in time with the ionizing pulse. This can lead to mass resolution problems and data degradation (see e.g., Miller, M. K. Atom Probe Tomography, Analysis at the Atomic Level, which is fully incorporated herein by reference).

### SUMMARY

The present invention is directed generally toward atom probe pulse energy, including methods for establishing atom probe data relationships between bias energies and pulse energies used in an atom probe. One aspect of the invention is directed toward an atom probe data relationship method that includes determining a first bias energy and a first pulse energy that when applied together to a first specimen in an atom probed will establish at least approximately a target evaporation rate. The first pulse energy includes a non-electric energy pulse. The method further includes determining a second bias energy and a second pulse energy that when applied together to a second specimen will establish at least approximately the target evaporation rate. The second pulse energy includes a non-electric energy pulse. The method still further includes establishing a data relationship between pulse energy and bias energy for the target evaporation rate, using the first and second bias energies and the first and second pulse energies. The method yet further includes (a) storing the data relationship, (b) using the data relationship to set at least one atom probe control parameter, or (c) both (a) and (b). In certain embodiments, establishing a data relationship can include determining an equivalent pulse fraction for a selected pulse energy and bias energy combination in the data relationship based on a local change in bias energy compared to a local change in pulse energy associated with the selected pulse energy and bias energy combination.

Another aspect of the invention is directed toward an atom probe data relationship method that includes determining a first bias energy and a first pulse energy combination that when applied to a first specimen in an atom probed will establish at least approximately a target evaporation rate. The first pulse energy includes a non-electric energy pulse. The method further includes determining a second bias energy and a second pulse energy combination that when applied to a second specimen will establish at least approximately the target evaporation rate. The second pulse energy includes a non-electric energy pulse. The method still further includes determining an equivalent pulse fraction for the first bias energy and the first pulse energy combination and/or the second bias energy and the second pulse energy combination based on the difference between the first bias energy and the second bias energy compared to the difference between the first pulse energy and the second pulse energy. The method yet further includes (a) storing the at least one equivalent pulse fraction, (b) using the at least one equivalent pulse fractions to set at least one atom probe control parameter, or (c) both (a) and (b).

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

### BRIEF DESCRIPTION OF THE DRAWINGS

FIG. 1 is a partially schematic illustration of an atom probe device that includes an atom probe assembly with an atom probe electrode in accordance with embodiments of the invention.

FIG. 2 is a flow diagram illustrating an atom probe data relationship method in accordance with certain embodiments of the invention.

FIG. 3 is a partially schematic illustration of a graph showing multiple bias energy and pulse energy combinations that will yield at least approximately a target Er in accordance with selected embodiments of the invention.

FIG. 4 is a partially schematic illustration of a specimen and a local electrode prior to an atom probe analysis/evaporation process in accordance with certain embodiments of the invention.

FIG. 5 is a partially schematic illustration of the specimen shown in FIG. 4 after at least a portion of an atom probe analysis/evaporation process in accordance with certain embodiments of the invention.

FIG. 6 is a partially schematic illustration of a graph that includes a data relationship between pulse energy and bias energy for a target evaporation rate in accordance with selected embodiments of the invention.

FIG. 7 is a flow diagram illustrating an atom probe data relationship method in accordance with other embodiments of the invention.

FIG. 8 is a partially schematic illustration of a portion of a process used to determine an equivalent pulse fraction in accordance with certain embodiments of the invention.

FIG. 9 is a partially schematic illustration of the data relationship shown in FIG. 3 where the derivative of the data relationship has been determined for a bias energy and pulse energy combination in accordance with selected embodiments of the invention.

### DETAILED DESCRIPTION

In the following description, numerous specific details are provided in order to give a thorough understanding of embodiments of the invention. One skilled in the relevant art will recognize, however, that the invention may be practiced without one or more of the specific details, or with other methods, components, materials, etc. In other instances, well known structures, materials, or operations are not shown or described in order to avoid obscuring aspects of the invention.

References throughout the specification to “one embodiment” or “an embodiment” means that a particular feature, structure, or characteristic described in connection with the embodiment is included in at least one embodiment of the present invention. Thus, the appearances of the phrase “in one embodiment” or “in an embodiment” in various places throughout the specification are not necessarily all referring to the same embodiment. Furthermore, the particular features, structures, or characteristics may be combined in any suitable manner in one or more embodiments.

Accordingly, various embodiments of the invention are described below. First, the structure and operation of atom probe devices are discussed. Then, various atom probe data relationship methods in accordance with embodiments of the invention are described. These methods and processes are suitable for use in an atom probe having features similar to those described with reference to the structure and operation of atom probe devices.

### A. Atom Probe Devices

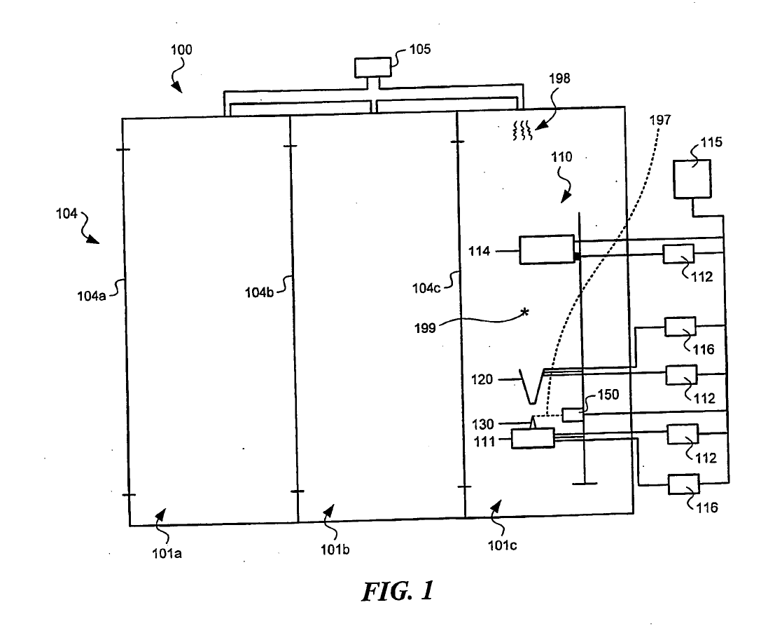

FIG. 1 is a partially schematic illustration of an atom probe device 100 in accordance with embodiments of the invention. In the illustrated embodiment, the atom probe device 100 includes a load lock chamber 101a, a buffer chamber 101b, and an analysis chamber 101c (shown collectively as chambers 101). The atom probe device 100 also includes a computer 115 and an atom probe assembly 110 having a specimen mount 111, an atom probe electrode 120, a detector 114, and an emitting device 150 (e.g., an emitting device configured to emit laser or photonic energy). The mount 111, electrode 120 and detector 114 can be operatively coupled to electrical sources 112. The electrode 120 and mount 111 can also be operatively coupled to temperature control devices 116 (e.g., cold/hot fingers that can provide contact cooling/heating to the atom probe electrode 120 and/or a specimen 130 carried by the mount 111). The emitting device 150, the detector 114, the voltage sources 112, and the temperature control devices 116 can be operatively coupled to the computer 115, which can control the analysis process, atom probe device operation, data analysis, and/or an image display.

In the illustrated embodiment, each chamber 101 is operatively coupled to a fluid control system 105 (e.g., a vacuum pump, turbo molecular pump, and/or an ion pump) that is capable of lowering the pressure in the chambers 101 individually. Additionally, the atom probe device 100 can include sealable passageways 104 (e.g., gate valves) positioned in the walls 106 of the chambers 101 that allow items to be placed in, removed from, and/or transferred between the chambers 101. In the illustrated embodiment, a first passageway 104a is positioned between the interior of the load loci chamber 101a and the exterior of the atom probe device 100, a second passageway 104b is positioned between the interior of the load lock chamber 101a and the interior of the buffer chamber 101b, and a third passageway 104c is positioned between the interior of the buffer chamber 101b and the interior of the analysis chamber 101c.

In FIG. 1, a specimen can be placed in the load lock chamber 101a via the first passageway 104a. All of the passageways 104 can be sealed and the fluid control system 105 can lower the pressure in the load lock chamber 101a (e.g., reduce the pressure to 10⁻⁶-10⁻⁷ torr). The pressure in the buffer chamber 101b can be set at approximately the same or a lower pressure than the load lock chamber 101a. The second passageway 104b can be opened, the specimen 130 can be transferred to the buffer chamber 101b, and the second and third passageways 104b and 104c can be sealed.

The fluid control system 105 can then lower the pressure in the buffer chamber 101b (e.g., reduce the pressure to 10⁻⁸-10⁻⁹ torr). The pressure in the analysis chamber 101c can be set at approximately the same or a lower pressure than the buffer chamber 101b. The third passageway 104c can be opened, the specimen 130 can be transferred to the analysis chamber 101c, and the third passageway 104c can be sealed. The fluid control system 105 can then reduce the pressure in the analysis chamber 101c (e.g., the pressure can be lowered to 10⁻¹⁰-10⁻¹¹ torr) prior to analysis of the specimen 130. In the illustrated embodiment, the fluid control system 105 can also be used to introduce selected fluids 198 (e.g., gases and/or liquid) and/or to control the composition of fluid in various atom probe chambers 110.

During analysis of the specimen 130, a positive electrical charge (e.g., a bias voltage or bias energy) can be applied to the specimen. The detector can be negatively charged and the electrode can be either grounded or negatively charged. A positive electrical pulse (e.g., an increase above the baseline energy or voltage) can be intermittently applied to the specimen 130 or a negative electrical pulse can be applied to the electrode 120. The electric field(s) created by the electrical charges can provide energy to ionize one or more atom(s) on the surface of the specimen 130. These ionized atom(s) 199 can separate or “evaporate” from the surface, pass though an aperture in the electrode 120, and impact the surface of the detector 114. As the specimen 130 is evaporated, a three-dimensional map of the specimen's constituents can be constructed. In other embodiments, the bias energy can include the energy difference (e.g., electrical potential and/or other type(s) of energy differential) between the specimen and the detector and/or the electrode when no pulse energy is present.

In certain embodiments, laser or photonic energy from the emitting device 150 can be used to emit an emission 197 (e.g., photons or laser light) to thermally pulse a portion of the specimen 130 to assist with the evaporation process (e.g., the removal of ionized atoms). This laser pulse can be in lieu of the electrical pulse discussed above or in addition to the electrical pulse. The total energy above the bias energy (e.g., a photonic energy pulse such as a laser pulse, an electrical pulse, an electron beam or packet, an ion beam, or some other suitable pulsed energy source) represents the pulse energy. The rate at which the pulse energy is applied is the pulse frequency.

In other embodiments, the atom probe device 100 can have more, fewer, and/or other arrangements of components. For example, in certain embodiments the atom probe device 100 can include more or fewer chambers, or no chambers. In other embodiments, the atom probe device can include multiple atom probe electrodes 120 and/or electrode(s) 120 having different configurations/placements (e.g., planar electrode(s)). In still other embodiments, the atom probe device 100 includes more, fewer, or different emitting devices 150; more, fewer, or different temperature control systems 116; and/or more, fewer or different electrical sources 112.

### B. Evaporation Processes and Associated Characteristics

As discussed above, during atom probe operation (e.g., atom probe analysis) it is important to control the evaporation rate (Er) to obtain desired results (e.g., desired mass resolution). Accordingly, atom probes include various control parameters that can be selected or set to establish a desired or target Er (e.g., in certain embodiments, a target Er can include a range such as, but not limited to, 0.1% (1 ion detected in 1,000 pulses) to 10% (1 ion detected in 100)). However, it is often difficult to know how to set the control parameters to obtain a target Er, especially when the bias energy and pulse energy used in a selected atom probe comprise more than one energy type. As discussed above, setting the control parameters so that they yield an Er that is too high or too low can result in inefficiencies, poor mass resolution, damage to the specimen, and/or damage to the atom probe itself.

In certain embodiments, the control parameters can include a bias energy, a pulse energy, pulse fraction (PF) (e.g., pulse voltage/bias voltage), and/or a target Er. For example, in selected embodiments a selected bias energy and a selected pulse energy can be set on an atom probe and applied to a specimen. For a certain operating condition, a selected pulse energy and a selected bias energy will yield a certain result (e.g., a certain Er, no Er, damage to the specimen, or the like). In some embodiments, if the initial result is undesirable, the pulse energy and/or the bias energy can be adjusted (e.g., in an attempt to obtain a desired or target Er). Of course, if the initial selected bias energy and pulse energy provided an initial Er that was too low or too high, the resulting process can be inefficient, can cause damage to the specimen, and/or can cause damage to the atom probe itself. Accordingly, it can be important to know where to set the initial bias and pulse energy.

In other embodiments, a target Er can be selected and an atom probe control system can adjust one or more other control parameters (e.g., pulse energy and/or bias energy) in an attempt to obtain the target Er (e.g., as described in International Patent Application No. PCT/US2006/029324, Attorney Docket No. 392458006WO, entitled ATOM PROBE EVAPORATION PROCESSES, filed Jul. 28, 2006, which is fully incorporated herein by reference). For example, in certain embodiments a target Er can be selected along with certain initial control parameters (e.g., a bias energy, pulse energy, PF, and/or the like). A control system (e.g., the computer 115 shown in FIG. 1) can then vary one or more control parameters in an attempt to attain the desired Er. Of course, if the initial selected parameters yield an initial Er that is too low or too high, the results can include analysis inefficiencies, damage to the specimen, and/or damage to the atom probe itself. Accordingly, it can be important to set the initial control parameters at least close to values that will yield the target Er.

In still other embodiments, a target PF can be selected along with a selected bias energy or pulse energy to define the bias energy and pulse energy that will be applied to the specimen. As discussed above, the bias energy and pulse energy combination will yield a certain result (e.g., a certain Er, no Er, damage to the specimen, or the like). In some embodiments, if the initial result is undesirable, adjustments can be made in an attempt to obtain a desired or target Er. However, if the initial selected bias energy and pulse energy yielded an initial Er that was too low or too high, the resulting process can be inefficient, can cause damage to the specimen, and/or can cause damage to the atom probe itself. Accordingly, it can be important to know where to set the initial PF, along with the initial bias energy or pulse energy.

In yet other embodiments, it can be desirable to use at least approximately a selected PF and total energy level that will yield at least approximately a target Er and/or to change the Er by varying the total energy level while maintaining at least approximately the selected PF (see e.g., Kellogg, G. L., Determining the Field Emitter Temperature during Laser Irradiation in the Pulsed Laser Atom Probe, J. Appl Phys. 52(8), August, 1981; Kellogg, Tsong, T. T., S. B. McLane, and T. J. Kinkus, Pulsed Laser time-of-flight atom-probe field ion microscope Review of Scientific Instruments 53(9), September 1982, both of which are fully incorporated herein by reference). In selected embodiments, if the initial PF and total energy levels are set too high or too low, the resulting process can be inefficient, can cause damage to the specimen, and/or can cause damage to the atom probe itself. Accordingly, it can be important to be able to calculate a PF associated with various atom probe operations.

Typically, a PF is defined as the pulse voltage/total voltage in an atom probe that only applies voltage energy to a specimen. Accordingly, it is generally difficult or impossible to calculate a meaningful PF when an atom probe applies more than one type of energy to a specimen (e.g., a voltage bias and a laser pulse, a voltage bias and a combination of a voltage and a laser pulse, or the like) because the various types of energies are expressed in different units. However, as discussed below in further detail, in selected embodiments an effective and/or equivalent pulse fraction can be determined or calculated for atom probes that apply multiple energy types to a specimen. For example, in certain embodiments an equivalent pulse fraction can be a non-dimensional representation of pulse energy/total energy. For instance, in selected embodiments an equivalent pulse fraction can be equivalent, proportional, and/or similar to a typical PF expressed as pulse voltage/total voltage. Accordingly, in certain embodiments an equivalent pulse fraction can be used in a manner similar to that discussed above with reference to a traditional PF, including as an atom probe control parameter.

Similarly, it can be difficult to make adjustments between bias energy and bias voltages to obtain a desired Er rate when an atom probe applies more than one type of energy to a specimen. For example, in certain embodiments it may be desired to increase the pulse energy and decrease the bias energy while maintaining at least approximately a target Er when the bias energy is close to or at a maximum limit. In other embodiments, it may be desirable to change the PF or equivalent pulse fraction while maintaining at least approximately a target Er. Accordingly, it can be important to understand the relationship between the various control parameters, including the relationship between pulse energy and bias energy for a target Er and to be able to determine an equivalent pulse fraction (e.g., an effective or voltage equivalent pulse fraction), particularly when the atom probe applies different types of energy to a specimen.

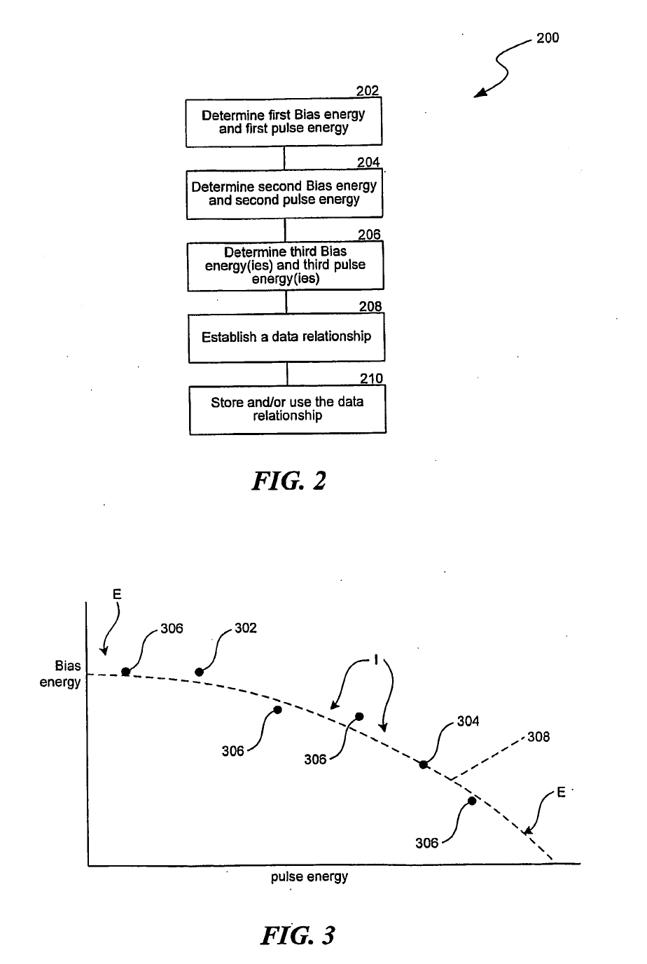

FIG. 2 is a flow diagram illustrating an atom probe data relationship method 200 in an atom probe in accordance with certain embodiments of the invention. In certain embodiments, the method 200 in FIG. 2 can include determining a first bias energy and a first pulse energy (process portion 202) and determining a second bias energy and a second pulse energy (process portion 204). In selected embodiments, the method can further include determining one or more third bias energies and third pulse energies (process portion 206). In certain embodiments the method 200 can also include establishing a data relationship (process portion 208), and storing and/or using the data relationship (process portion 210). The method 200 can be particularly useful when more than one type of energy is applied to a specimen in an atom probe.

For example, in certain embodiments determining a first bias energy and a first pulse energy (process portion 202) can include determining a first bias energy and a first pulse energy (e.g., bias and pulse energy combination) that when applied together to a first specimen in an atom probed will establish at least approximately a target evaporation rate, wherein the first pulse energy includes a non-electric energy pulse. Additionally, determining a second bias energy and a second pulse energy (process portion 204) can include determining a second bias energy and a second pulse energy that when applied together to a second specimen will establish at least approximately the target evaporation rate, wherein the second pulse energy includes a non-electric energy pulse. Establishing a first data relationship (process portion 208) can then include establishing a data relationship between pulse energy and bias energy for the target evaporation rate, using the first and second bias energies and the first and second pulse energies.

In certain embodiments, first and second bias energies can include first and second bias voltages and the first and second pulse energies can include first and second pulse energies comprised of a non-electric energy pulse that does not include applying an electrical current or voltage to the specimen. For example, the non-electric energy (e.g., non-voltage energy or non-electric field producing energy) can include a photonic energy pulse such as a laser pulse, an electron beam or packet, an ion beam, or some other suitable pulsed energy source that may be electrically driven, but does not involve applying an electric current or voltage to the specimen. In selected embodiments, the pulse energy can include a combination of a voltage or electric pulse and a non-electric energy pulse. For example, in certain embodiments where the pulse energy includes a combination of a voltage pulse and a laser pulse, as the magnitude of the pulse energy is varied, the magnitude of the voltage pulse can remain constant and the magnitude of a laser pulse can be varied. In other embodiments where the pulse energy includes a combination of a voltage pulse and a non-electric energy pulse, the electric pulse and non-electric pulse can be varied using a selected relationship (e.g., a voltage pulse increases 100 volts for every 1 nJ a laser energy pulse is increased).

In selected embodiments, determining a first bias energy and a first pulse energy can include placing a specimen in an atom probe and applying an initial bias energy (e.g., a bias voltage). A first pulse energy (e.g., photonic energy or laser pulse pulses applied at a selected frequency) can then be applied. The bias energy can then be varied while the pulse energy remains (e.g., is held) at least approximately constant until a target evaporation rate is at least approximately established (e.g., manually or using a control system as discussed above). Accordingly, a first bias energy and a first pulse energy combination that at least approximately produces or yields a target evaporation rate can be determined.

Similarly, determining a second bias energy and a second pulse energy can include applying a second pulse energy (e.g., photonic energy or laser pulses applied at a selected frequency) having a different magnitude than the first pulse energy to the specimen. The bias energy (e.g., bias voltage) can be varied while the pulse energy remains at least approximately constant until the same target evaporation rate is at least approximately established. Accordingly, a second bias energy (e.g. bias voltage) and a second pulse energy combination that at least approximately produces or yields a target evaporation rate can be determined.

In other embodiments, a first bias energy and first pulse energy combination can be determined by applying and maintaining a first bias energy at least approximately constant while varying the pulse energy (e.g., varying the magnitude of the pulse energy) until a target Er is at least approximately established. Similarly, a second bias energy and second pulse energy combination can be determined by applying and maintaining a second bias energy at least approximately constant while varying the pulse energy until the same target Er is at least approximately established. Accordingly, a second bias energy and a second pulse energy combination that at least approximately produces or yields a target evaporation rate can be determined.

As discussed above, in selected embodiments, establishing a data relationship (process portion 208) can include using the first bias energy and first pulse energy combination, along with the second bias and pulse energy combination, to establishing a data relationship between pulse energy and bias energy for the target evaporation rate. For example, in certain embodiments numerical and/or graphical methods can be used to establish a data relationship with additional bias energy and pulse energy combinations that will yield at least approximately the target Er via interpolate and/or extrapolate techniques. The data relationship can then be stored (e.g., in a computer, displayed and written down by an operator, printed out, reduced to one or more formulas, in one or more tables (e.g., in a look-up table), in graphical form, and/or the like) and/or used (process portion 210). In other embodiments, the data relationship can be used to set at least one atom probe control parameter. For example, the data relationship can be used to set a bias energy and/or a pulse energy in an atom probe to establish at least approximately the target Er (e.g., used for manually establishing at least approximately a target Er, used to set initial parameters in an atom probe that uses a control system to achieve at least approximately a target Er, and/or used by an automated control system).

In certain embodiments, the method 200 can include determining one or more third bias energies and third pulse energies (process portion 208), for example, wherein each third bias energy and pulse energy combination includes a non-electric energy pulse (process portion 206). The one or more third bias energy and third pulse energy combinations can then be used along with the first and second bias energy and pulse energy combinations to establish the data relationship. For example, in selected embodiments these additional points can aid on establishing fitting a curve to the data and/or establishing one or more formulas to represent the data relationship.

FIG. 3 is a partially schematic illustration of a graph showing multiple bias energy and pulse energy combinations that will yield at least approximately a target Er. In FIG. 3, the first pulse energy and first bias energy are shown as first pulse energy and bias energy combination 302. The second pulse energy and second bias energy are shown as second pulse energy and bias energy combination 304. Third pulse energies and third bias energies are shown as third pulse and bias energy combinations 306. The data relationship 308 in FIG. 3 is shown as a curve that has been fit to the collected pulse energy and bias energy combinations. In FIG. 3, area I indicate areas where additional pulse energy and bias energy combinations have been calculated/interpolated and areas E show areas where additional pulse energy and bias energy combinations have been calculated/extrapolated. In selected embodiments, the graph in FIG. 3 can be normalized for bias energy and/or pulse energies (e.g. where 1 is the maximum value). In other embodiments, the bias energy and/or pulse energy can be represented in their base units (e.g., bias energy in voltage and pulse energy in nJ). In still other embodiments, the data relationship 308 in FIG. 3 can also be represented by one or more formulas and/or presented in tabular form.

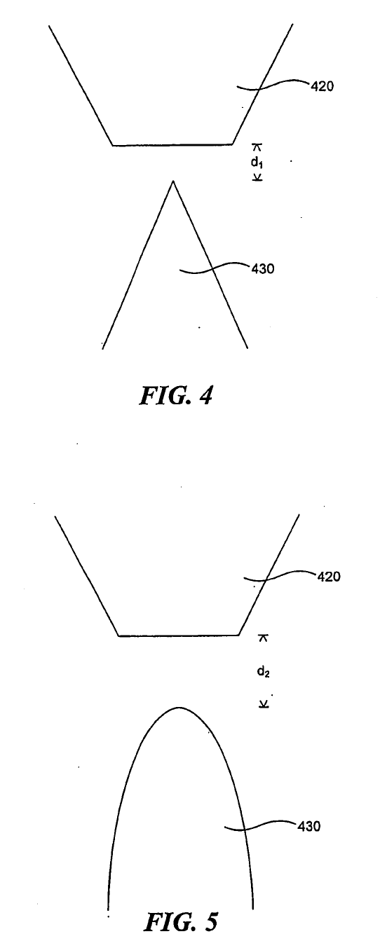

In certain cases, various atom probe operating conditions (e.g., the type of material being analyzed on the specimen, the distance a specimen is from an electrode, the shape of the specimen, the pressure in the atom probe analysis chamber, the composition of gas in the atom probe analysis chamber, the temperature of the specimen, and/or the temperature in the atom probe analysis chamber) can affect the bias and pulse energy combination required to yield at least approximately a target Er. For example, as shown in FIG. 4, prior to atom probing, a specimen 430 can have a sharp tip located a first distance d₁ from a local electrode 420. After at least a portion of an atom probe analysis/evaporation process has run for a selected period of time, the specimen 430 can have a tip that is less sharp and that is located a second distance d₂ from the local electrode 420, as shown in FIG. 5. In certain embodiments, the bias and pulse energy combination required to obtain at least approximately a target Er for the specimen electrode combination shown in FIG. 4 will be different than the bias and pulse energy combination required to obtain at least approximately the target Er for the specimen electrode combination shown in FIG. 5.

Accordingly, some of the scatter of the collected bias energy and pulse energy combinations shown in FIG. 3 as compared to the data relationship 308 can be caused, at least in part, by performing the steps to determine a bias energy pulse energy combination using subsequent runs on the same specimen (e.g., where the specimen changes shape as it evaporates). In some cases, this scatter can be desirable because it can provided a more generalized data relationship that provides bias energy and pulse energy combinations that will at least approximately yield the target Er over small variation in operating conditions. Accordingly, in certain embodiments it can be desirable to determine the first, second, and/or third bias energy and pulse energy combinations using the same specimen (or to vary other atom probe operating conditions when collecting/determining these combinations).

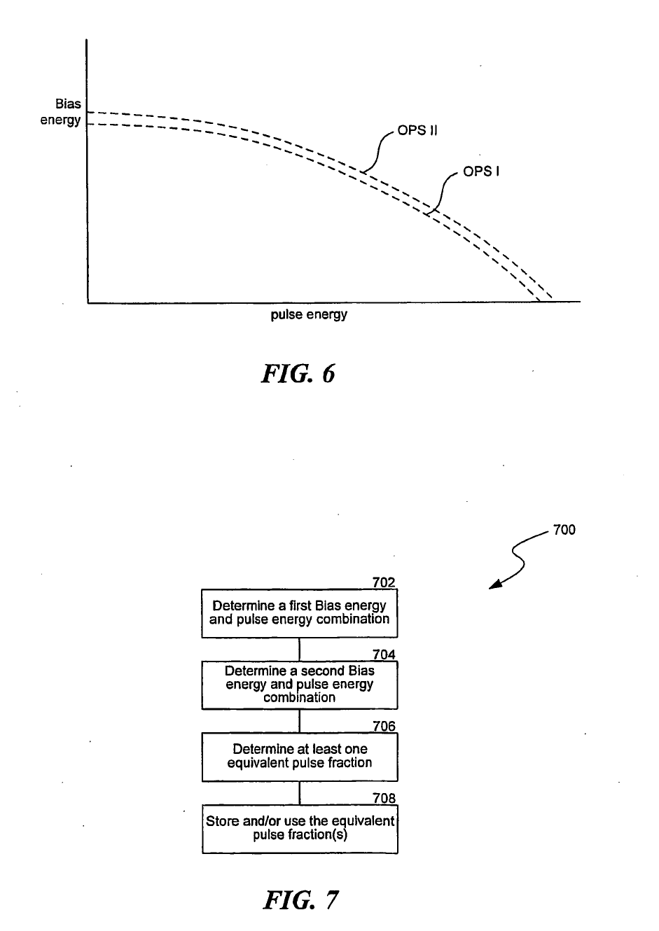

In other embodiments, it can be desirable to use different specimens (e.g., different specimens, each having a similar shape and composition) when determining each of these bias energy and pulse energy combinations so that the variation in the shape of the specimen tip and the distance between the specimen tip and the electrode are minimized between the collection of bias energy and pulse energy combinations. In still other embodiments, variations in operating conditions can be used to develop data relationship that include multiple curves, wherein each curve is related to a different set of operating conditions. For example, FIG. 6 is a partially schematic illustration of a graph that includes a data relationship with two curves, one for a first set of operating conditions (OPS I) and the other for a second set of operating conditions (OPS II). Of course in other embodiments the data relationship shown in FIG. 6 could be stored in a different form (e.g., one or more formulas, a table, and/or the like).

As discussed above, in selected embodiments it can be desirable to calculate/determine an equivalent pulse fraction (e.g., a voltage equivalent pulse fraction) for atom probe processes that apply multiple types of energy to a specimen. In certain embodiments, the local change in bias energy compared to a local change in pulse energy associated with a selected pulse energy and bias energy combination can be used to calculate/determine an equivalent pulse fraction for the selected pulse energy and bias energy combination. For example, as discussed above, a typical PF can be defined as the ratio of the pulsed voltage (Vₚᵤₗₛₑ) with the total specimen voltage (Vₜₒₜₐₗ); PF=Wₚᵤₗₛₑ/Vₜₒₜₐₗ. Where Vₜₒₜₐₗ=V_{bias}+Vₚᵤₗₛₑ, the PF can also be defined or written as PF=[Nₜₒₜₐₗ−V_{bias}]/Vₜₒₜₐₗ.

In many cases, the above definitions of pulse fraction do not relate well to atom probe using a laser pulsing (or other types of non-electric energy pulses) because it is difficult to express all of the energy terms in consistent and/or meaningful set of units. For example, when the above PF ratios are expressed for an atom probe that applies a voltage bias and a laser pulse or another type of energy pulse having non-volt units (e.g., nJ/nm², W/cm², etc.) to a specimen, the units do not coincide with the volts units used to express V_{bias}. Accordingly, it can be desirable to express PF in terms of a voltage (e.g., an applied voltage, electrical potential, and/or electric field) required to induce ionization at a specified temperature (V_{i,T=To}). Assuming V_{i,T=To} is Vₜₒₜₐₗ, PF can be written as, or defined as, PF=[V_{i,T=To}−V_{bias}]/V_{i,T=To} where T₀ is defined as the temperature of the specimen prior to any excitation from the laser or other type of energy pulse (e.g., the bias voltage required to evaporate the specimen at a target Er without any pulse energy). This definition can be used to determine an equivalent pulse fraction for a selected pulse energy and bias energy combination based on the local change in bias energy compared to a local change in pulse energy associated with the selected pulse energy and bias energy.

For example, as shown in FIG. 7, in selected embodiments an atom probe data relationship method 700 can include determining a first bias energy and pulse energy combination (process portion 702) and determining a second bias energy and pulse energy combination (process portion 704). The method 700 can further include determining at least one equivalent pulse fraction (process portion 706). The method 700 can still further include storing and/or using the equivalent pulse fraction(s) (process portion 708).

In selected embodiments, determining a first bias energy and pulse energy combination (process portion 702) can include determining a first bias energy and a first pulse energy combination that when applied to a first specimen in an atom probed will establish at least approximately a target evaporation rate, wherein the first pulse energy includes a non-electric energy pulse. Determining a second bias energy and pulse energy combination (process portion 704) can include determining a second bias energy and a second pulse energy combination that when applied to a second specimen will establish at least approximately the target evaporation rate, wherein the second pulse energy includes a non-electric energy pulse. Determining or finding the first bias energy and pulse energy combination and the second bias energy and pulse energy combination can be accomplished in a manner similar to that discussed above (with reference to FIGS. 2-6) for determining first and second bias energies and first and second pulse energies.

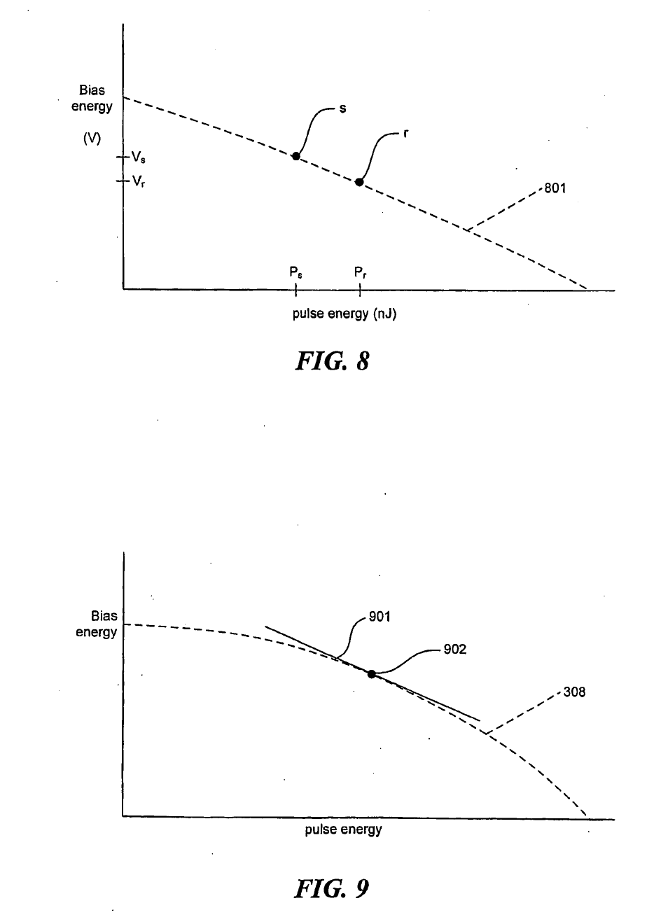

In FIG. 8 a first bias energy and a first pulse energy combination s and a second bias energy and a second pulse energy combination r have been determined for an atom probe that applies a bias energy in the form of voltage and a pulse energy in the form of a laser pulse. Accordingly, combination s includes a bias energy Vs and a pulse energy Ps, and combination r includes a bias energy Vr and a pulse energy Vs. Both bias energy and pulse energy combinations yield at least approximately the same target Er. By comparing the change in bias energy to the change in pulse energy between points s and r (e.g., comparing the local rate of change or slope between points s and r) an effective or equivalent PF (EPF) can be determined using linear regression (e.g., using the equation for a line, y=mx+b).

For example, assuming y=bias energy (e.g., volts) and x=pulse energy (e.g., nJ) a line 801 can be drawn through combinations s and r as shown in FIG. 8. Accordingly, m is the slope of line 801 or the rate of change between bias energy as compared to the rate of change of pulse energy (e.g., m=(Vr−Vs)/(Pr−Ps) and has the units of volts/nJ). Additionally, b is the y intercept, which in this case would be bias energy (e.g., volts) required to yield at least approximately the Er with zero pulse energy (based on the local slope of the line 801); V_{iT=To} (e.g., Vₜₒₜₐₗ). Because m is expressed in (bias energy units)/(pulse energy units) (e.g., volts/nJ), the equation for the line 801 becomes V_{bias}=mPₚᵤₗₛₑ+Vₜₒₜₐₗ. Using combinations s and r, the equation can be written as Vr=([(Vr−Vs)/(Pr−Ps)]*Pr)+V_{iT=To}. Accordingly, V_{iT}=_{To}=Vr−([(Vr−Vs)/(Pr−Ps)]*Pr). Once V_{iT=To} is calculated, the equivalent pulse fraction (EPF) for combination r can be determined using the equation EPF=[V_{i,T=To}−V_{bias}]/V_{i,T=To} as EPFr=[V_{i,T=To}−Vr]/V_{i,T=To} (e.g., substituting the above expression for V_{iT=To} into this equation EPFr can also be expressed as −([(Vr−Vs)/(Pr−Ps)]*Pr)/V_{i,T=To}). In a similar manner, the equivalent pulse fraction for combination s can be determined as EPFs=[V_{i,T=To}−Vs]/V_{i,T=To} (e.g., or similarly EPFs can also be expressed as −([(Vr−Vs)/(Pr−Ps)]*Ps)/V_{i,T=To}).

Accordingly, given combinations s and r the equivalent pulse fraction associated with each combination can be calculated, determined, and/or established based on the difference between the first bias energy and the second bias energy compared to the difference between the first pulse energy and the second pulse energy. Therefore, determining at least one equivalent pulse fraction (process portion 706) can include determining an equivalent pulse fraction for at least one of the first bias energy and the first pulse energy combination and the second bias energy and the second pulse energy combination based on the difference between the first bias energy and the second bias energy compared to the difference between the first pulse energy and the second pulse energy. Once the pulse fraction(s) have been determined they can be stored and/or used (process portion 708).

For example, storing and/or using the equivalent pulse fraction(s) (process portion 708) can include (a) storing the at least one equivalent pulse fraction, (b) using the at least one equivalent pulse fractions to set at least one atom probe control parameter, or (c) both (a) and (b). For example, in selected embodiments the equivalent pulse fraction(s) can be saved for use in an atom probe analysis data reduction process and/or for later use in selecting control parameters for an atom probe process. In certain embodiments, saving an equivalent pulse fraction can include saving a pulse fraction in a computer, displaying the equivalent pulse fraction, printing the equivalent pulse fraction, and/or other ways of providing the equivalent pulse fraction to an operator for future use. In other embodiments, the equivalent pulse fraction(s) can be used (e.g., via manual control, automated control, or a combination of the two) to make a correction during an atom probe analysis process and/or a series of atom probe analysis processes.

For instance, the equivalent pulse fraction can be used in an atom probe that uses a bias voltage and laser pulse energy to make adjustments when it is necessary to increase/decrease the total amount of energy being applied to the specimen. Accordingly, in one embodiment, if an atom probe is being operated at a first bias voltage and a first laser pulse energy combination (associated with a target Er) and it becomes desirable to increase/decrease the total energy while keeping the equivalent pulse fraction at least approximately the same, the pulse energy can be increased/decrease slightly. The bias voltage can then be adjusted to achieve the target Er, providing a second bias voltage and a second laser pulse combination for the target Er. Using these two combinations the local change in bias energy can be compared to the local associated change in pulse energy and an equivalent pulse fraction can be determined for the first bias voltage and pulse energy combination (e.g., as described above with reference to FIGS. 7 and 8).

This equivalent pulse fraction can be used to determine a third bias energy and a third pulse energy combination that has a higher or lower total energy than the first bias energy and first pulse energy combination (e.g., and may have a different Er), but has at least approximately the same equivalent pulse fraction. For example, assuming the equivalent pulse fraction is held constant when the total energy is increased/decreased, it can be assumed that the local change in bias energy as compared to the local change in pulse energy will remain constant (e.g., m in the equation V_{bias}=mPₚᵤₗₛₑ+Vₜₒₜₐₗ discussed above with reference to FIGS. 7 and 8 remains constant). Accordingly, since EPF and m are known constants, the relationship EPF=[V_{i,T=To}−V_{bias}]/V_{i,T=To} and the relationship V_{bias}=mPₚᵤₗₛₑ+Vₜₒₜₐₗ (both discussed above with reference to FIGS. 7 and 8) can be used to solve for a new Pₚᵤₗₛₑ and a new V_{bias} given a selected Vₜₒₜₐₗ, to solved for a new V_{bias} given a selected Pₚᵤₗₛₑ, or to solve for a new Pₚᵤₗₛₑ given a selected V_{bias}. Accordingly, a third bias energy and a third pulse energy combination can be determined having a different total energy, but the same equivalent pulse fraction as the first bias energy and first pulse energy combination.

Therefore, using the equivalent pulse fraction(s) can include calculating a third pulse energy and a third bias energy that will provide at least approximately the same equivalent pulse fraction as determined for the first bias energy and the first pulse energy combination, and setting the atom probe to the third bias energy and the third pulse energy combination. In other embodiments, a similar process can be used to calculate or determine a third pulse energy and a third bias energy combination that will provide at least approximately the same equivalent pulse fraction as the equivalent pulse fraction determined for the second bias energy and the second pulse energy combination discussed above, and the atom probe can be set to apply the third bias energy and the third pulse energy combination to the specimen. In still other embodiments, once Vₜₒₜₐₗ has been determined, a bias energy and pulse energy combination associated with at least approximately a selected EPF (e.g., wherein the selected EPF represents a small change from the calculated EPF) can be determined using the equations EPF=[V_{i,T=To}−V_{bias}]/V_{i,T=To} and V_{bias}=mPₚᵤₗₛₑ+Vₜₒₜₐₗ. Although the above embodiment has been discussed with reference to an atom probe using a voltage bias energy and a laser pulse energy, one skilled in the art will recognize that the same process can be used with atom probes using other energy type combinations. Additionally, an alternate definition of pulse fraction can be PF=Vₚᵤₗₛₑ/V_{bias}. One skilled in the art will recognize that the techniques and processes discussed above can be applied to this alternate definition in a manner similar to that discussed above.

A similar process can also be used to determine and/or use an equivalent pulse fraction once at least a portion of a data relationship between pulse energy and bias energy for the target evaporation rate has been established (e.g., similar to the data relationship shown in FIG. 3). For example, two bias energy and pulse energy combinations in the data relationship can be selected and an equivalent pulse fraction can be determined, saved, and/or used in a manner similar to that discussed above with reference to FIGS. 7 and 8. In other embodiments, the local change in bias energy as compared to the local change in pulse energy (e.g., a derivative of a point or combination of the data relationship), which can represent the slope m in the V_{bias}=mPₚᵤₗₛₑ+Vₜₒₜₐₗ equation discussed above with reference to FIGS. 7 and 8.

For example, FIG. 9 is a partially schematic illustration of the data relationship 308, shown in FIG. 3, where the derivative (e.g., local slope 902) of the data relationship has been determined for a bias energy and pulse energy combination 901. As discussed above, since this derivative or slope 902 represent the local change in bias energy as compared to the local change in pulse energy, it can be used as m in the equation V_{bias}=mPₚᵤₗₛₑ+Vₜₒₜₐₗ. Accordingly, using the associated bias energy (e.g., V_{bias}) and pulse energy (e.g., Pₚᵤₗₛₑ) combination along with m, Vₜₒₜₐₗ can be determined (e.g., Vₜₒₜₐₗ can be determined based on the local slope m for the purpose of determining an EPF associated with the combination 901 and may or may not be the actual y intercept of the data relationship 308). Once Vₜₒₜₐₗ has been determined, the equations EPF=[V_{i,T=To}−V_{bias}]/V_{i,T=To} can be used to determine the equivalent pulse fraction associated with the combination 901.

In selected embodiments, establishing a data relationship (process portion 208 in FIG. 2) can include determining an equivalent pulse fraction for a selected pulse energy and bias energy combination (e.g., combination 901) in the data relationship based on a local change in bias energy compared to a local change in pulse energy associated with the selected pulse energy and bias energy combination. Accordingly, the equivalent pulse fraction can be saved and/or used as part of the data relationship (process portion 210 in FIG. 2). For example, in selected embodiments saving an equivalent pulse fraction can include saving a pulse fraction as part of the data relationship, saving the pulse fraction in a computer, displaying the equivalent pulse fraction (e.g., so that it can be manually recorded), printing the equivalent pulse fraction, and/or other ways of providing the equivalent pulse fraction to an operator for future use. In other embodiments, the equivalent pulse fraction can be saved or used separately.

In other embodiments, establishing a data relationship (process portion 208 in FIG. 2) can include determining an equivalent pulse fraction for a selected pulse energy and bias energy combination (e.g., combination 901) in the data relationship based on a local change in bias energy compared to a local change in pulse energy associated with the selected pulse energy and bias energy combination. Saving and/or using the data relationship (process portion 210 in FIG. 2) can then include using the equivalent pulse fraction to calculate a new pulse energy and bias energy combination having at least approximately the equivalent pulse fraction that will yield an evaporation rate different than the target evaporation rate and setting the new pulse energy and bias energy combination. For example, as discussed above, once the EPF and the Vₜₒₜₐₗ associated with the combination 901 are known, the equations EPF=[V_{i,T=To}−V_{bias}]/V_{i,T=To} and V_{bias}=mPₚᵤₗₛₑ+Vₜₒₜₐₗ can be used to determine/calculate a new pulse energy and bias energy combination that has a higher or lower total energy than the first bias energy and first pulse energy combination, but has at least approximately the same equivalent pulse fraction.

For instance, as discussed above, assuming the equivalent pulse fraction is held constant when the total energy is increased/decreased, it can be assumed that the local change in bias energy as compared to the local change in pulse energy will remain constant (e.g., m remains constant). Accordingly, since EPF and m are known constants, the relationship EPF=[V_{i,T=To}−V_{bias}]/V_{i,T=To} and the relationship V_{bias}=mPₚᵤₗₛₑ+Vₜₒₜₐₗ can be used to solve for a new Pₚᵤₗₛₑ and a new V_{bias} given a selected Vₜₒₜₐₗ, to solved for a new V_{bias} given a selected Pₚᵤₗₛₑ, or to solve for a new Pₚᵤₗₛₑ given a selected V_{bias}.

In still other embodiments, once Vₜₒₜₐₗ has been determined for the bias energy and pulse energy combination 901, a new bias energy and pulse energy combination associated with at least approximately a new selected EPF (e.g., wherein the selected EPF represents a small change from the calculated EPF) can be determined using the equations EPF=[V_{i,T=To}−V_{bias}]/V_{i,T=To} and V_{bias}=mPₚᵤₗₛₑ+Vₜₒₜₐₗ. In yet other embodiments, saving and/or using the data relationship (process portion 210 in FIG. 2) can include selecting an equivalent pulse fraction and determining a pulse energy and bias energy combination in the data relationship that has at least approximately the selected equivalent pulse fraction based on a local change in bias energy compared to a local change in pulse energy associated with the pulse energy and bias energy combination. Using the data relationship can further include setting the pulse energy and bias energy combination. This process can be useful in selected embodiments where it is desired to operate the atom probe at a target Er and a selected equivalent pulse fraction.

While many of the embodiments discussed above have been discussed with reference to an atom probe using a bias voltage and a laser pulse, one skilled in the art will recognize that other energy combinations can be used. For example, in other embodiments the pulse energy can include various forms of energy and can include varying pulse rates. For example, in certain embodiments the pulse energy can include one or more of the following: a voltage pulse, an electron beam or packet, an ion beam, a laser pulse, or some other suitable pulsed source.

From the foregoing, it will be appreciated that specific embodiments of the invention have been described herein for purposes of illustration, but that various modifications may be made without deviating from the invention. Additionally, aspects of the invention described in the context of particular embodiments may be combined or eliminated in other embodiments. Although advantages associated with certain embodiments of the invention have been described in the context of those embodiments, other embodiments may also exhibit such advantages. Additionally, not all embodiments need necessarily exhibit such advantages to fall within the scope of the invention. Accordingly, the invention is not limited except as by the appended claims.

1. An atom probe data relationship method, comprising:
determining a first bias energy and a first pulse energy that when applied together to a first specimen in an atom probed will establish at least approximately a target evaporation rate, wherein the first pulse energy includes a non-electric energy pulse;
determining a second bias energy and a second pulse energy that when applied together to a second specimen will establish at least approximately the target evaporation rate, wherein the second pulse energy includes a non-electric energy pulse;
establishing a data relationship between pulse energy and bias energy for the target evaporation rate, using the first and second bias energies and the first and second pulse energies; and
(a) storing the data relationship, (b) using the data relationship to set at least one atom probe control parameter, or (c) both (a) and (b).

2. The method of claim 1 wherein:
determining a first bias energy and a first pulse energy includes:
applying a first pulse energy; and
varying bias energy to determine the first bias energy, wherein the first bias energy and the first pulse energy establish at least approximately the target evaporation rate; and
determining a second bias energy and a second pulse energy includes:
applying a second pulse energy; and
varying bias energy to determine the second bias energy, wherein the second bias energy and the second pulse energy establish at least approximately the target evaporation rate.

3. The method of claim 1 wherein the first specimen and the second specimen are the same specimen.

4. The method of claim 1, further comprising determining one or more third bias energy and pulse energy combinations that will establish at least approximately the target evaporation rate, wherein each third bias energy and pulse energy combination includes a non-electric energy pulse, establishing a data relationship includes establishing a data relationship between pulse energy and bias energy for the target evaporation rate, using the first and second bias energies, the first and second pulse energies, and the one or more third bias energy and pulse energy combinations.

5. The method of claim 1, further comprising determining one or more third bias energy and pulse energy combinations that will establish at least approximately the target evaporation rate, wherein each third bias energy and pulse energy combination includes a non-electric energy pulse, establishing a data relationship includes establishing a data relationship between pulse energy and bias energy for the target evaporation rate, using the first and second bias energies, the first and second pulse energies, and the third bias energy and pulse energy combinations, and wherein the first, second, and one or more third specimens are the same specimen.

6. The method of claim 1 wherein storing the data relationship includes storing the data relationship as one or more formulas, in one or more tables, or in graphical form.

7. The method of claim 1, further comprising determining one or more third bias energy and pulse energy combinations that will establish at least approximately the target evaporation rate, wherein each third bias energy and pulse energy combination includes a non-electric energy pulse, establishing a data relationship includes establishing a data relationship between pulse energy and bias energy for the target evaporation rate, using the first and second bias energies, the first and second pulse energies, and the one or more third bias energy and pulse energy combinations, wherein the first bias energy and first pulse energy are determined at a different atom probe operating condition than the atom probe operating condition at which the second bias energy and second pulse energy is determined or one of the one or more third bias energy and pulse energy combinations is determined.

8. The method of claim 1 wherein the first and second bias energies include first and second bias voltages.

9. The method of claim 1 wherein the first pulse energy includes photonic energy and wherein the second pulse energy includes photonic energy.

10. The method of claim 1 wherein establishing a data relationship includes determining an equivalent pulse fraction for a selected pulse energy and bias energy combination in the data relationship based on a local change in bias energy compared to a local change in pulse energy associated with the selected pulse energy and bias energy combination.

11. The method of claim 1 wherein establishing a data relationship includes determining an equivalent pulse fraction for a selected pulse energy and bias energy combination in the data relationship based on a local change in bias energy compared to a local change in pulse energy associated with the selected pulse energy and bias energy combination, and wherein using the data relationship to set at least one atom probe control parameter includes using the equivalent pulse fraction to calculate a new pulse energy and bias energy combination having at least approximately the equivalent pulse fraction that will yield an evaporation rate different than the target evaporation rate and setting the new pulse energy and bias energy combination.

12. The method of claim 1 wherein using the data relationship to set at least one atom probe control parameter includes selecting an equivalent pulse fraction and determining a pulse energy and bias energy combination in the data relationship that has at least approximately the selected equivalent pulse fraction based on a local change in bias energy compared to a local change in pulse energy associated with the pulse energy and bias energy combination, and setting the pulse energy and bias energy combination.

13. An atom probe data relationship method, comprising:
determining a first bias energy and a first pulse energy combination that when applied to a first specimen in an atom probed will establish at least approximately a target evaporation rate, wherein the first pulse energy includes a non-electric energy pulse;
determining a second bias energy and a second pulse energy combination that when applied to a second specimen will establish at least approximately the target evaporation rate, wherein the second pulse energy includes a non-electric energy pulse;
determining an equivalent pulse fraction for at least one of the first bias energy and the first pulse energy combination and the second bias energy and the second pulse energy combination based on the difference between the first bias energy and the second bias energy compared to the difference between the first pulse energy and the second pulse energy; and
(a) storing the at least one equivalent pulse fraction, (b) using the at least one equivalent pulse fractions to set at least one atom probe control parameter, or (c) both (a) and (b).

14. The method of claim 13 wherein:
determining a first bias energy and a first pulse energy combination includes:
applying a first pulse energy; and
varying bias energy to determine the first bias energy, wherein the first bias energy and the first pulse energy establish at least approximately the target evaporation rate; and
determining a second bias energy and a second pulse energy combination includes:
applying a second pulse energy; and
varying bias energy to determine the second bias energy, wherein the second bias energy and the second pulse energy establish at least approximately the target evaporation rate.

15. The method of claim 13 wherein the first and second bias energies include first and second bias voltages.

16. The method of claim 13 wherein the first pulse energy includes photonic energy and wherein the second pulse energy includes photonic energy.

17. The method of claim 13 wherein using the at least one equivalent pulse fractions to set at least one atom probe control parameter includes calculating a third pulse energy and a third bias energy that will provide at least approximately the same equivalent pulse fraction as at least one of the equivalent pulse fractions determined for at least one of the first bias energy and the first pulse energy combination and the second bias energy and the second pulse energy combination and setting the atom probe to the third bias energy and the third pulse energy combination.

18. The method of claim 13 wherein the first specimen and the second specimen are the same specimen.

19. An atom probe data relationship method, comprising:
determining a first bias voltage and a first pulse energy that when applied together to a specimen in an atom probed will establish at least approximately a target evaporation rate, wherein the first pulse energy includes a non-electric energy pulse;
determining a second bias voltage and a second pulse energy that when applied together to the specimen will establish at least approximately the target evaporation rate, wherein the second pulse energy includes a non-electric energy pulse;
establishing a data relationship between pulse energy and bias voltage for the target evaporation rate, using the first and second bias voltages and the first and second pulse energies; and
(a) storing the data relationship, (b) using the data relationship to set at least one atom probe control parameter, or (c) both (a) and (b).

20. An atom probe data relationship method, comprising:
determining a first bias voltage and a first pulse energy combination that when applied to a specimen in an atom probed will establish at least approximately a target evaporation rate, wherein the first pulse energy includes a non-electric energy pulse;
determining a second bias voltage and a second pulse energy combination that when applied to the specimen will establish at least approximately the target evaporation rate, wherein the second pulse energy includes a non-electric energy pulse;
determining an equivalent pulse fraction for at least one of the first bias voltage and the first pulse energy combination and the second bias voltage and the second pulse energy combination based on the difference between the first bias voltage and the second bias voltage compared to the difference between the first pulse energy and the second pulse energy; and
(a) storing the at least one equivalent pulse fraction, (b) using the at least one equivalent pulse fractions to set at least one atom probe control parameter, or (c) both (a) and (b).
